(19) United States
(12) Patent Application Publication
(10) Pub. No.: US 2025/0218959 A1
(43) Pub. Date: Jul. 3, 2025

(54) PAD DESIGN FOR EMBEDDED INTERCONNECT BRIDGES IN PACKAGE SUBSTRATES

(71) Applicant: Intel Corporation, Santa Clara, CA (US)

(72) Inventors: Minglu LIU, Chandler, AZ (US); Yosuke KANAOKA, Chandler, AZ (US); Bai NIE, Chandler, AZ (US); Srinivas PIETAMBARAM, Chandler, AZ (US); Gang DUAN, Chandler, AZ (US)

(21) Appl. No.: 18/398,868

(22) Filed: Dec. 28, 2023

(51) Int. Cl. H01L 23/538; H01L 21/48; H01L 23/00; H01L 25/065; H10B 80/00

(52) U.S. Cl. CPC H01L 23/5386; H01L 21/4857; H01L 23/5383; H01L 23/5384; H01L 25/0655; H10B 80/00; H01L 24/14; H01L 24/16; H01L 2224/1403; H01L 2224/14177; H01L 2224/16227

(57) ABSTRACT

Semiconductor chip package substrates having interconnect bridges, assemblies including these semiconductor chip package substrates, and methods of manufacturing interconnect-bridge-containing semiconductor package chip substrates are provided. The interconnect bridges can include through-bridge vias that are electrically coupled to the semiconductor package substrate. The embedded bridges can be aligned to fiducials within the semiconductor package substrate.

### FIELD

Descriptions are generally related to semiconductor manufacture, and more particular descriptions are related to packaging semiconductor chips, package substrates for semiconductor chips, and interconnect bridges.

### BACKGROUND

Semiconductor chips are central to intelligent devices and systems, such as personal computers, laptops, tablets, phones, servers, and other consumer and industrial products and systems. Manufacturing semiconductor chips presents a number of challenges and these challenges are amplified as devices become smaller and performance demands increase. Challenges include, for example, unwanted material interactions, precision and scaling requirements, power delivery requirements, limited failure tolerance, and material and manufacturing costs.

High performance computing (HPC) applications, such as for example, artificial intelligence (AI) inferencing and chat generative pre-trained transformer (ChatGPT), are driving a significant package form-factor increase. Proposals for computing systems for HPC applications include integrating six times a silicon reticule size and more than 16 high bandwidth memory (HBM) units (die stacks) into a package. HBM can consist of stacks of dynamic random access memory (DRAM) dies. Semiconductor chip package assemblies that include multiple semiconductor chips can include interconnect bridges, such as, for example embedded multi-die interconnect bridges (EMIBs) and/or EMIBs having through-bridge vias (EMIB-T) structures in the package. Interconnect bridges can provide interconnections between semiconductor chips within a package.

### BRIEF DESCRIPTION OF THE DRAWINGS

The figures are provided to aid in understanding the invention. The figures can include diagrams and illustrations of exemplary structures, assemblies, data, methods, and systems. For ease of explanation and understanding, these structures, assemblies, data, methods, and systems, the figures are not an exhaustively detailed description. The figures therefore should not be understood to depict the entire metes and bounds of structures, assemblies, data, methods, and systems possible without departing from the scope of the invention. Additionally, features are not necessarily illustrated relatively to scale due in part to the small sizes of some features and the desire for clarity of explanation in the figures.

FIG. 1 illustrates a semiconductor package assembly that includes an interconnect bridge in a package substrate.

FIGS. 2A-2C provide a section of a semiconductor package substrate having an interconnect bridge.

FIGS. 3A-3D describe a method of manufacturing a semiconductor package substrate that includes an interconnect bridge.

FIG. 4 shows an exemplary multi-chip package in which the package incorporates interconnect bridges.

FIG. 5 provides an exemplary computing system.

Descriptions of certain details and implementations follow, including non-limiting descriptions of the figures, which depict some examples and implementations.

### DETAILED DESCRIPTION

References to one or more examples are to be understood as describing a particular feature, structure, or characteristic included in at least one implementation of the invention. The phrases “one example” or “an example” are not necessarily all referring to the same example or embodiment. Any aspect described herein can potentially be combined with any other aspect or similar aspect described herein, regardless of whether the aspects are described with respect to the same figure or element.

The words “connected” and/or “coupled” can indicate that two or more elements are in direct physical or electrical contact with each other. The term “coupled,” however, can also mean that two or more elements are not in direct contact with each other and are instead separated by one or more elements but they may still co-operate or interact with each other, for example, physically, magnetically, or electrically.

The words “first,” “second,” and the like, do not indicate order, quantity, or importance, but rather are used to distinguish one element from another. The words “a” and “an” herein do not indicate a limitation of quantity, but rather denote the presence of at least one of the referenced items. The terms “follow” or “after” can indicate immediately following or following some other event or events. Other sequences of operations can also be performed according to alternative embodiments. Furthermore, additional operations may be added or removed depending on the application.

Disjunctive language such as the phrase “at least one of X, Y, or Z,” is used in general to indicate that an element or feature, may be either X, Y, or Z, or any combination thereof (e.g., X, Y, and/or Z). Thus, this disjunctive language should be understood not to imply that certain embodiments require at least one of X, at least one of Y, or at least one of Z to each be present.

Flow diagrams as illustrated herein provide examples of sequences of various process actions. The flow diagrams can indicate operations to be executed by a software or firmware routine, as well as physical operations. Physical operations can be performed by semiconductor processing equipment. Although shown in a particular sequence or order, unless otherwise specified, the order of the actions can be modified. Thus, the illustrated diagrams should be understood only as examples, and the process can be performed in a different order, and some actions can be performed in parallel. Additionally, one or more actions can be omitted and not all implementations will perform all actions.

Various components described can be a means for performing the operations or functions described. Each component described can include software, hardware, or a combination of these. Some components can be implemented as software modules, hardware modules, special-purpose hardware (for example, application specific hardware, application specific integrated circuits (ASICs), digital signal processors (DSPs), etc.), embedded controllers, or hardwired circuitry). Other components can be semiconductor processing and/or testing equipment that is able to perform physical operations such as, for example, lithography, laser drilling, electrodeposition, chemical vapor deposition, atomic layer deposition, and/or sputtering, chemical mechanical polishing, and/or etching.

To the extent various computer operations or functions are described herein, they can be described or defined as software code, instructions, configuration, and/or data. The software content can be provided via an article of manufacture with the content stored thereon, or via a method of operating a communication interface to send data via the communication interface. A machine-readable storage medium can cause a machine to perform the functions or operations described. A machine-readable storage medium includes any mechanism that stores information in a tangible form accessible by a machine (e.g., computing device), such as recordable/non-recordable media (e.g., read only memory (ROM), random access memory (RAM), magnetic disk storage media, optical storage media, flash memory devices). Instructions can be stored on the machine-readable storage medium in a non-transitory form. A communication interface includes any mechanism that interfaces to, for example, a hardwired, wireless, or optical medium to communicate to another device, such as, for example, a memory bus interface, a processor bus interface, an Internet connection, a disk controller.

Terms such as chip, die, IC (integrated circuit) chip, IC die, microelectronic chip, microelectronic die, semiconductor die, and/or semiconductor chip are interchangeable and refer to a semiconductor device comprising integrated circuits.

Semiconductor chip manufacturing processes are sometimes divided into front end of the line (FEOL) processes and back end of the line (BEOL) processes. Electronic circuits and active and passive devices within the chip, such as for example, transistors, capacitors, resistors, and/or memory cells, are manufactured in what can be referred to as FEOL processes. Memory cells include, for example, electronic circuits for random access memory (RAM), such as static RAM (sRAM), dynamic RAM (DRAM), read only memory (ROM), non-volatile memory, and/or flash memory. FEOL processes can be, for example, complementary metal-oxide semiconductor (CMOS) processes. BEOL processes include metallization of the chip where interconnects are formed in layers and the feature size of the interconnect increases in layers nearer the surface of the semiconductor chip. Interconnects in, for example, semiconductor chips that are integrated into heterogeneous packages (such as, for example, packages that include memory and logic chips), can also include through silicon vias (TSVs) that transverse the semiconductor chip device region. Semiconductor devices that have TSVs can blur distinctions between BEOL and FEOL processes.

Semiconductor chip interconnects can be created by forming a trench or though-layer via by etching a trench or via structure into a dielectric layer and filling the trench or via with metal. Dielectric layers can comprise, for example, low-κ dielectrics, SiO₂, silicon nitride (SiN), silicon carbide (SiC), and/or silicon carbonitride (SiCN). Low-κ dielectrics include for example, fluorine-doped SiO₂, carbon-doped SiO₂, porous SiO₂, porous carbon-doped SiO₂, combinations for the foregoing, and also these materials with airgaps. Dielectric layers that include metallic features can be intermetal dielectric (ILD) features.

The terms “package,” “packaging,” “IC package,” or “chip package,” “microelectronics package,” or “semiconductor chip package” are interchangeable and generally refer to an enclosed carrier of one or more dies, in which the dies are attached to a package substrate and encapsulated. The package substrate provides electrical interconnects between the die(s) and other dies and/or a motherboard, a board, a mainboard, a logic board or a printed circuit board (PCB) for I/O (input/output) communication and power delivery. A package with multiple dies can, for example, be a system in a package.

A package substrate generally includes dielectric layers or structures having conductive structures on, through, and/or embedded in the dielectric layers. The dielectric layers can be, for example, build-up layers. Dielectric materials include Ajinomoto build-up film (ABF), although other dielectric materials are possible. Semiconductor package substrates can have cores or be coreless. Semiconductor packages having cores can have dielectric layers such as buildup layers on more than one side of a core, such as on two opposite sides of a core. Cores can include through-core vias that contain a conductive material. Other structures or devices are also possible within a package substrate.

A “core” or “package core” generally refers to a layer usually embedded within a package substrate. The core can provide structure or stiffness to a package substrate. A core is an optional feature of a package substrate. The core can be a dielectric organic or inorganic material and may have conductive vias extending through the layer. The conductive vias can include a metal, for example, copper. A package core can, for example, be comprised of a glass material (such as, for example, aluminosilicate, borosilicate, alumino-borosilicate, silica, and fused silica), silicon, silicon nitride, silicon carbide, gallium nitride, or aluminum oxide. In some examples, core materials are glass-fiber reinforced organic resins such as epoxy-based resins. A further example package substrate core is FR4 (woven glass fiber reinforces epoxy). In other examples, package substrate cores are solid amorphous glass materials.

In further examples of a package substrate core, the substrate core is a glass core comprising a solid amorphous glass material. The glass substrate core can comprise a glass such as, for example, aluminosilicate, borosilicate, alumino-borosilicate, silica, and fused silica, that additionally optionally comprises one or more of the following: Al₂O₃, B₂O₃, MgO, CaO, SrO, BaO, SnO₂, Na₂O, K₂O, SrO, P₂O₃, ZrO₂, Li₂O, Ti, and/or Zn. In further examples of glass cores, the glass can comprise silicon and oxygen, as well as optionally any one or more of: aluminum, boron, magnesium, calcium, barium, tin, sodium, potassium, strontium, phosphorus, zirconium, lithium, titanium, and/or zinc. In some examples, a glass package substrate core comprises at least 23% silicon, at least 26% oxygen by weight. In further examples, the glass package substrate core comprises at least 23% silicon, at least 26% oxygen, and at least 5% aluminum by weight.

Additionally, exemplary solid amorphous glass substrate cores can be considered to have a rectangular prism volume. The rectangular prism volume can contain vias that have been filled with one or more different materials. A material in a via can be a conducting metal such as copper. Exemplary solid amorphous glass substrate cores can have a thickness in the range of 50 μm to 1.4 mm. Additionally, the package substrate can include a multi-layer glass substrate. The package substrate in this example may be a coreless substrate. The multi-layer glass substrate can have a thickness, for example, in the range of 25 μm to 50 μm. Further, glass substrate cores can have dimensions on a side of 10 mm to 250 mm. For example, the substrate core can be 10 mm by 10 mm up to 250 mm by 250 mm in two dimensions, but substrate cores do not necessarily have to have the same value in both dimensions.

Package substrates can include interconnect bridges, such as, for example, embedded multi die interconnect bridges (EMIBs) and EMIBs that include through-bridge vias (TBVs) which can be called EMIB-T. The interconnect bridges have been demonstrated to be a cost-effective packaging technology, and assemblies including interconnect bridges are sometimes referred to as 2.5D assemblies. Interconnect bridges can enable heterogeneous semiconductor device integration and improve high performance computing at a system level. Interconnect bridges that include TBVs can enable direct power delivery through the bridge die which can further improve performance of systems.

A package substrate can include one or more interconnect bridges. The interconnect bridge can be partially, fully, or not embedded into the package substrate. An interconnect bridge provides interconnects between chips that are housed on the package substrate. The interconnects can be for I/O between the chips. Some interconnect bridges, such as ones that have metallic through-bridge vias, can also provide power to an operably connected chip. The interconnect bridge can include regions having traces that have a smaller width dimension (the smallest dimension of the trace), a smaller height dimension, and/or a length dimension than the vias and traces of the surrounding package substrate. For example, width dimensions (or smallest dimension) can be 3 μm or less and/or 10 μm or less in some regions. The interconnect bridges can also have smaller trace spacings than the surrounding package substrate. For example, trace center-to-center spacings can be 3 μm and/or less or 10 μm or less in some regions. The bridge can comprise, for example, a silicon substrate, a silicon-on-insulator substrate, a float glass substrate, a borosilicate glass substrate, a silicon dioxide substrate, and/or a silicon nitride substrate. The substrate can comprise, for example, one or more dielectric layers that are comprise of, silicon oxides, silicon nitride, silicon oxynitride, carbon-doped oxide, methyl silsesquioxane, hydrogen silsesquioxane, die backside film (DBF), an epoxy film, a B-stage epoxy film, other dielectric material. The bridge can also be a coreless substrate comprised of a plurality of dielectric layers. The dielectric layers can be, for example, die backside film (DBF), an epoxy film, a B-stage epoxy film, other dielectric material. Other materials are possible.

For packages that include interconnect bridges, the pitch in the interconnect bridge region for first level interconnects (FLIs) assemblies can be less than the pitch for other regions of the FLI assembly. The pitch in the interconnect bridge region can be, for example, less than or equal to 25 μm. A low regression bump thickness variation (rBTV) can be more difficult to obtain in mixed pitch systems where there are pitches are less than or equal to 25 μm. A larger rBTV can negatively impact package assembly yields.

Thermal compression bonding (TCB) can employ solder on a die or solder on both the die and the package substrate to form solder joint FLIs. The chip gap height (CGH) control across the die to substrate plane is critical and can be compensated for by pre-measurement of rBTV and bond head tilt to achieve a quality controlled collapse chip connection (C4) bonding. After formation of solder joint FLIs, an epoxy underfill is dispensed to encapsulate the C4 interface to enhance reliability.

The package substrate manufacturing process includes laser drill and lithographic processes that can induce via-to-pad overlay errors. These overlay errors can lead to first level interconnect bump true position shift for interconnect bridges in relation to package substrate bumps. Bump true position shifts can be as great as 20 μm. Overlay errors can have a significant negative impact on packaging process yields.

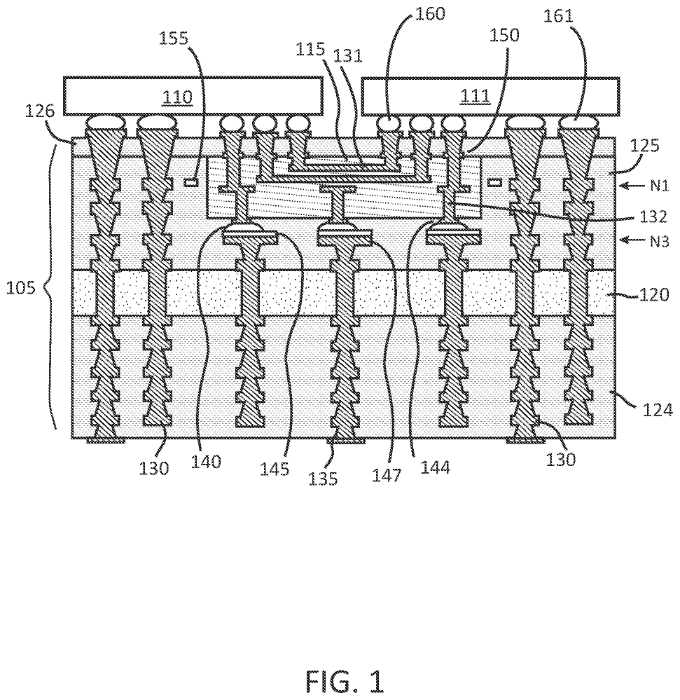

FIG. 1 shows a cross-sectional view of an assembly that includes a package substrate 105 and semiconductor chips 110 and 111. Package substrate 110 includes interconnect bridge 115. The interconnect bridge 115 includes through-bridge vias 132. The interconnect bridge 115 contains metallic vias and traces 131 that allow the operably connected semiconductor chips 110 and 111 to communicate with each other. The interconnect bridge 115 includes metallic through-bridge vias (TBVs) 132 that can supply power and the interconnect bridge 115 can be for example, an EMIB-T. The package substrate 105 in this example includes a package substrate core 120 which can be an organic core or a glass core as described herein. Package substrates 105 can also be coreless package substrates and package substrate core 120 is optional. Additionally, the package substrate 105 has a dielectric regions 124, 125, and 126 which can be one or more layers of dielectric (such as build-up layers) having metallic traces and vias 130 and board-side pads 135. Board-side pads 135 can connect to a board (e.g., a motherboard, a PCB, a system board, a logic board, or a main board). Connection to a board can be through solder joints. The metallic traces and vias 130 can be, for example, comprised of copper.

The interconnect bridge 115 is connected to a subset of metallic traces and vias 130 through conducting interconnections 140 which can be, for example, comprised of solder. The solder can be, for example, a tin-based alloy that includes silver. The package-side interconnections for the interconnect bridge 115 also include a landing pad surface coating 145 on the package-side interconnect bridge landing pads 144. The landing pad surface coating 145 can change the contact behavior of the metallic interconnections 140 so that the metallic interconnections 140 partially surface wet, fully surface wet, or surface and side-wall wet the package-side interconnect bridge landing pads 144. The landing pad surface coating 145 can be a material such as, for example, NiPdAu, NiAu, and/or organic solderability preservatives (OSPs). The landing pad surface coating 145 can be layers of materials, such as metals, where the surface layer is Au. Organic solderability preserve compounds for surface coating can be azoles, such as benzotriazoles, imidazoles, and benzimidazoles. The package-side interconnect bridge landing pads 144 are shown in this illustration as being in the “N2” buildup layer of the package substrate 105. Other designs are possible for a package substrate 105, such as, for example, ones where the package-side interconnect bridge landing pads 144 are in the N3 or N4 layer.

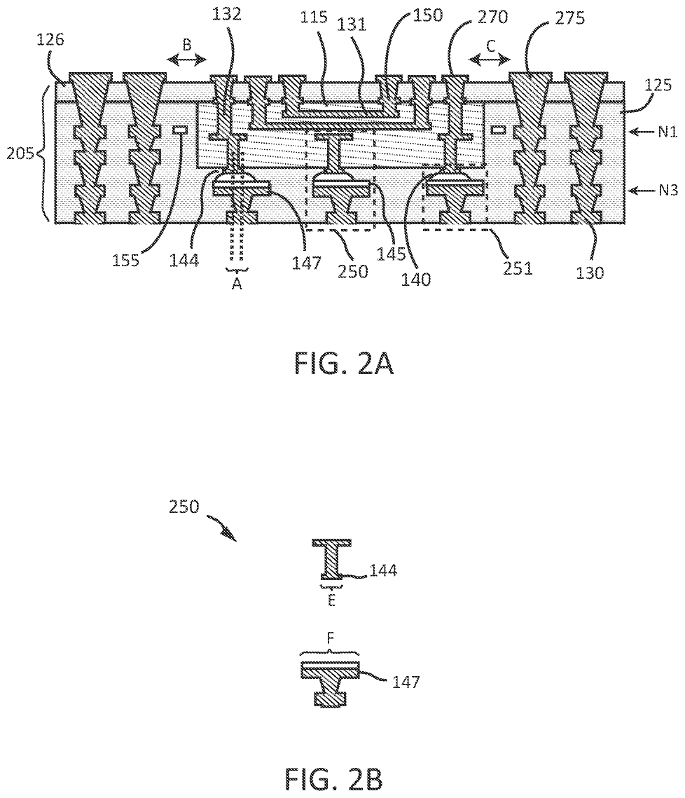

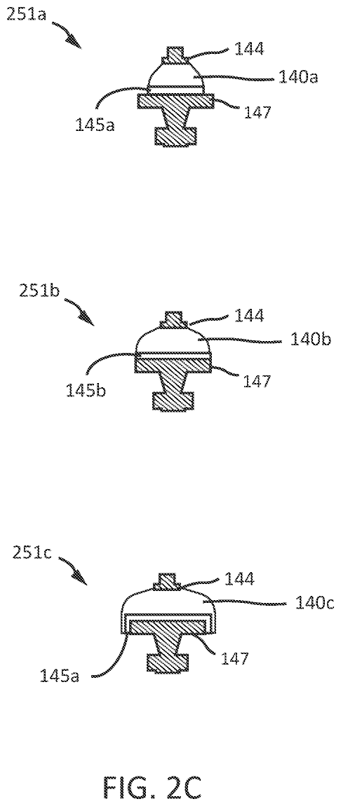

As illustrated further in FIGS. 2A-2C, the larger size of the interconnect bridge-side package landing pads 147 relative to the package-side interconnect bridge landing pads 144 allows mis-alignment of the interconnect bridge-side package landing pads 147 and the package-side interconnect bridge landing pads 144 during bonding between the interconnect bridge 115 and the package substrate 105. Advantageously, the mis-alignment relative to the N2 layer interconnect regions (in this example), allows alignment instead of the chip-side interconnect bridge landing pads 150 to the N1 layer of the package substrate 105 which can facilitate the formation of FLIs with semiconductor chips 110 and 111. The alignment of the chip-side interconnect bridge landing pads 150 can be done, for example, with respect to optional fiducials 155. Interconnects 160 and 161 between the semiconductor chips 110 and 111 can, for example, include solder.

FIGS. 2A-2C further illustrate features of a semiconductor package substrate that includes an interconnect bridge having TBVs 275. In FIGS. 2A-2C, numbering of parts is in some instances the same as for FIG. 1. Where numbering is the same in FIGS. 2A-2C and FIG. 1, the description herein for FIG. 1 can be used with respect to FIGS. 2A-2C. FIG. 2A illustrates a section of a semiconductor package 205 that includes dielectric regions 125 and 126 which can be one or more layers of dielectric (such as build-up layers) having metallic traces and vias 130. The section of a semiconductor package 20 has an interconnect bridge 115 that includes traces 131 and TBVs 270. In FIG. 2A, a partial view of a partial package substrate 105 illustrates the misalignment that is possible between the package-side interconnect bridge landing pads 144 and of the interconnect bridge-side package landing pads 147. A center-to-center misalignment indicated by dashed lines and distance “A” (the separation between the dashed lines) in FIG. 2A can be in a range of 0 μm to 30 μm, a range of 5 μm to 30 μm, or a range of 10 μm to 30 μm. The center-to-center misalignment indicated by “A” allows the alignment of the interconnect bridge-associated landing pads 270 on the package substrate 205 with the package substrate-associated landing pads 275 as indicated by arrows “B” and “C.”

FIG. 2B illustrates region 250 (demarcated with a dashed line) from FIG. 2A that has been expanded along one axis and has through metallic interconnection 140 removed for ease of explanation. The misalignment that is possible between package-side interconnect bridge landing pads 144 and of the interconnect bridge-side package landing pads 147 is facilitated by the size differential between them. In FIG. 2B, “E” indicates a dimension of the between package-side interconnect bridge landing pads 144 which can be, for example, 10 μm to 70 μm. The dimension indicated by “E” is a dimension of the between interconnect bridge-side package landing pads 147 which can be, for example, 10% to 200%, 20% to 200%, 50% to 200%, or 75% to 200% larger than the package-side interconnect bridge landing pads 144. Depending on the footprint of the pad, the dimensions “E” and/or “F” can be, for example, a diameter of a circle or a length of a side of a rectangular shape if the pad has a circular shape or a rectangular shape on one side.

FIG. 2C illustrates some example configurations (251a, 251b, and 251c) of interconnections in region 251 (demarcated with a dashed line) from FIG. 2A. In example configuration 251a, the landing pad surface coating 145a partially covers a surface of the interconnect bridge-side package landing pads 147 and interconnection region 140a is comprised of a flowable material, such as a solder, and the solder has partially wet a surface of the surface coating 145 the interconnect bridge-side package landing pads 147. In example configuration 251b, the landing pad surface coating 145b covers a surface of the interconnect bridge-side package landing pads 147 and interconnection region 140b is comprised of a flowable material, such as a solder, and the solder has wet a surface of the surface coating 145 of the interconnect bridge-side package landing pads 147. A partial or a full wet of a surface of the surface coating 145 of the interconnect bridge-side package landing pads 147 is possible for example configuration 251b. In example configuration 251c, the landing pad surface coating 145c covers a surface and at least partially covers the sides of the interconnect bridge-side package landing pads 147. Interconnection region 140c is comprised of a flowable material, such as a solder, and the solder has wet a surface of the interconnect bridge-side package landing pads 147 and at least partially wet the sides of the interconnect bridge-side package landing pads 147. The solder can be, for example, a tin-based alloy that includes silver. The landing pad surface coatings 145a, 145b, and/or 145c can be a material such as, for example, NiPdAu, NiAu and/or organic solderability preservatives (OSP). Organic solderability preserve compounds for surface coating can be azoles, such as benzotriazoles, imidazoles, and benzimidazoles. The landing pad surface coatings 145a, 145b, and/or 145c can be layers of materials, such as metals, where the surface layer is Au.

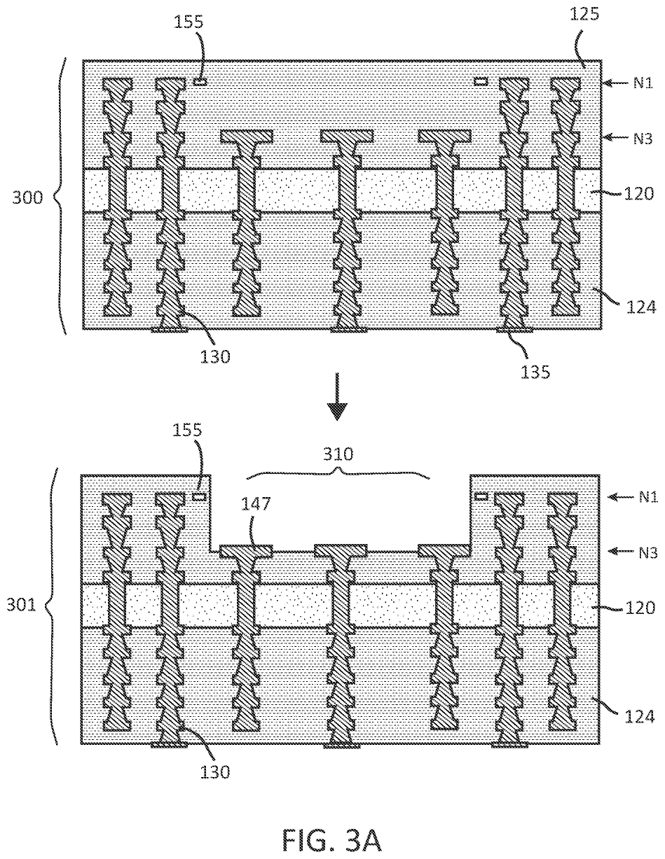

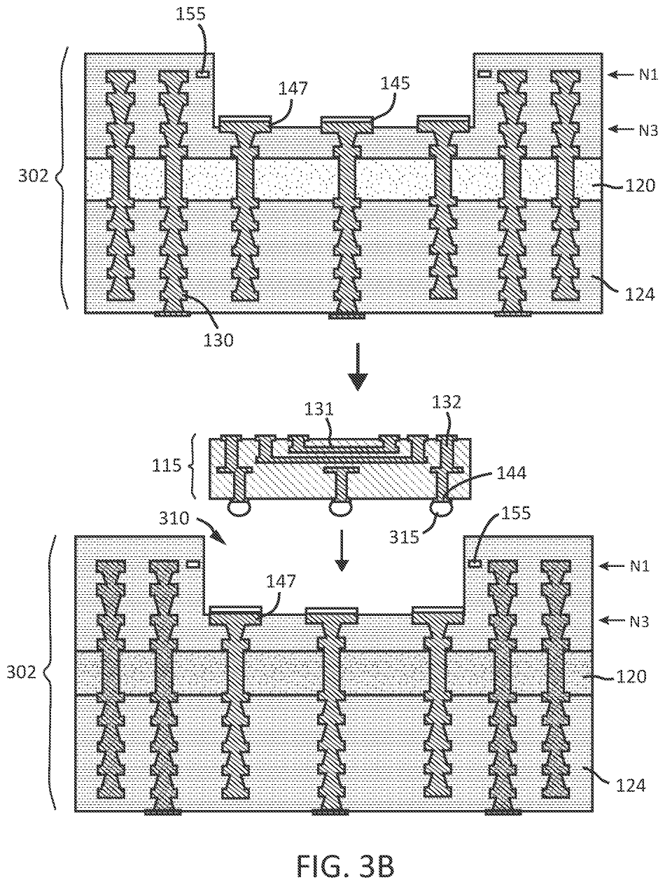

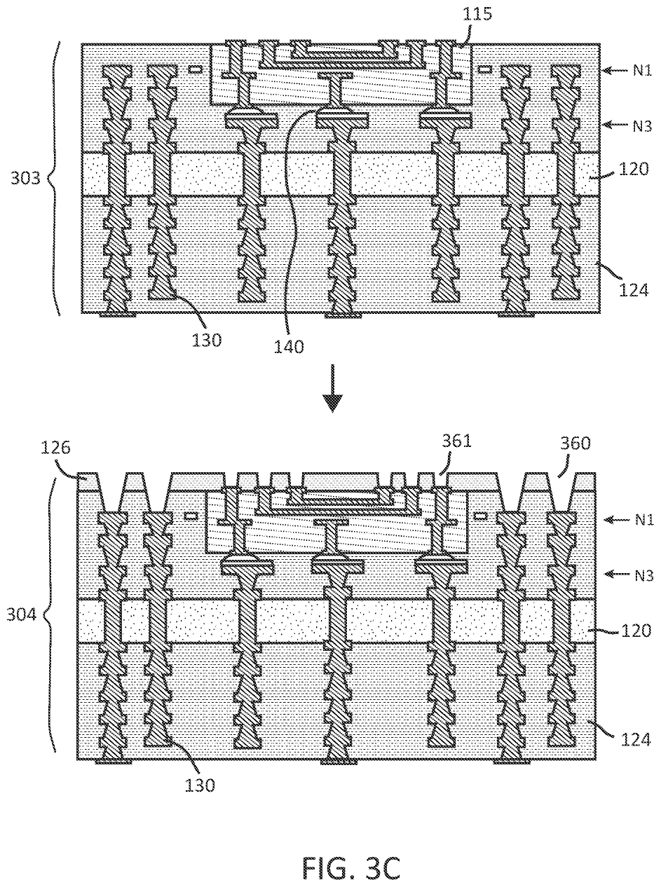

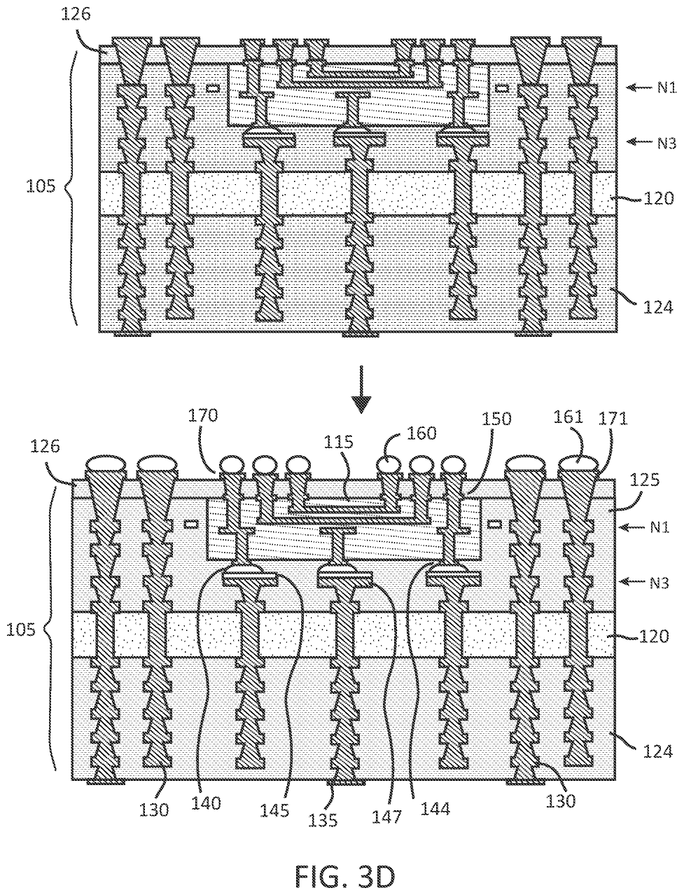

FIGS. 3A-3D describe a method for manufacturing a package substrate that includes an interconnect bridge that has TBVs. In FIGS. 3A-3D, numbering of parts is in some instances the same as for FIG. 1. Where numbering is the same in FIGS. 3A-3D and FIG. 1, the description herein for FIG. 1 can be used with respect to FIGS. 3A-3D. In FIG. 3A, a partially completed package substrate 300 includes an optional package substrate core 120, however the partially completed package substrate 300 can also be a coreless package substrate. A laser cavity drill process creates cavity 310 in partially completed package substrate 300 creating partially completed package substrate 301. The laser cavity drill process exposes interconnect bridge-side package landing pads 147.

In FIG. 3B, a surface coating 145 is applied to the exposed interconnect bridge-side package landing pads 147 of partially manufactured package substrate 301 creating partially manufactured package substrate 302. In this example, a surface coating 145 that is similar to the surface coating of FIG. 2C example configuration 251b, however any of the surface coating 145 configurations of FIG. 2C are possible (for example, 251a or 251c). The surface coating 145 can be a material such as, for example, NiPdAu, NiAu, and/or organic solderability preservatives (OSP). For NiPdAu and NiAu surface coating 145 materials, the last surface layer can be comprised of Au. The surface coating 145 can be applied using electroless plating, electroplating, and/or other coating processes. Organic solderability preserve compounds for surface coating can be azoles, such as benzotriazoles, imidazoles, and benzimidazoles. These azoles typically are water soluble and can be applied, for example, in solution form.

An interconnect bridge 115 having vias and traces 131, TBVs 132, and solder 315 on package-side interconnect bridge landing pads 144 is placed into cavity 310 of partially manufactured package substrate 302. The solder can be, for example, a tin-based alloy that includes silver. The package-side interconnect bridge landing pads 144 and the interconnect bridge-side package landing pads 147 have pad size differences as described herein, for example, with respect to FIGS. 2A-2C. The larger size of the interconnect bridge-side package landing pads 147 can allow the interconnect bridge 115 to be aligned with optional fiducials 155 or other features of partially manufactured package substrate 302 instead of aligning with the interconnect bridge-side package landing pads 147 during assembly. The interconnect bridge 115 is attached to partially manufactured package substrate 302 through solder 315 wetting of the surface coating 145 of the interconnect bridge-side package landing pads 147 which creates metallic interconnects 140. Joining the interconnect bridge 115 to the package substrate can be achieved through a thermocompression bonding process with heat and pressure and accurate control of solder collapse and chip gap height. An underfill material is placed between the interconnect bridge 115 and the partially manufactured package substrate 302 creating partially manufactured package substrate 303 of FIG. 3C. Different underfill processes and materials are possible and can be applied during or post die attach processes. These include, for example, capillary underfills (CUF), mold underfills (MUF), non-conductive films (NCF). and non-conductive pastes (NCP).

In FIG. 3C, a dielectric layer 126 can be deposited or laminated onto a surface of partially manufactured package substrate 303. The dielectric layer 125 can be, for example, ABF. Via cavities 360 and 361 can be laser drilled into the dielectric layer 126 to form partially manufactured package substrate 304. Vias can also be formed by a dry reactive ion etch process. Conducting material is deposited into via cavities 360 and 361 to create package substrate 105 of FIG. 3D. The conducting material can be, for example, copper. Deposition can be done by an electrodeposition process. Bond pads 170 and 171 (FLI bond pads) can be formed, for example, on the surface of vias through the lateral overgrowth of metallic material during electrodeposition or they can be lithographically patterned with a deposition mask. Interconnect material, such as solder, is attached to (or deposited on through a mask) FLI bond pads 170 and 171 forming interconnects 160 and 161 for semiconductor chip attachment. A thermocompression bonding process can be used for semiconductor chip attachment.

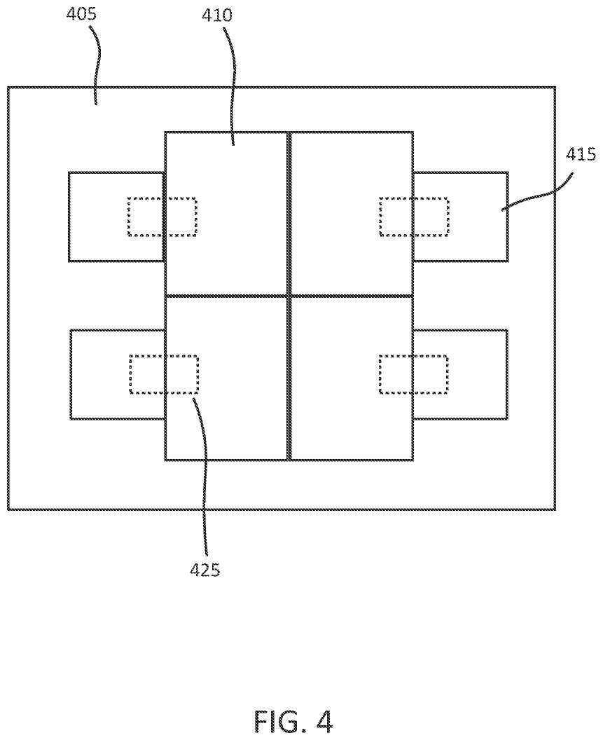

FIG. 4 shows an exemplary configuration for packaged semiconductor chips mounted on a board. Many other configurations are possible. FIG. 4 can be considered a top-down view in relation to FIG. 1 which can be considered a cross-section view of packaged semiconductor chips. In FIG. 4, a board 405 (e.g., a motherboard, a printed circuit board, a system board, a logic board, a circuit board, or a main board) has packaged semiconductor chips 410 and 415 operably coupled to the board 405. Interconnect bridges 425 are shown with a dashed line and are covered by packaged semiconductor chips 410 and 415 in this view. The interconnect bridges 425 can be more than one interconnect bridge, can be interconnect bridges that are with or without TBVs, and the semiconductor chip package substrates can contain more than one type of interconnect bridge. The interconnect bridges can be mounted in the package substrate as described herein with respect to FIGS. 1, 2A-2C, and 3A-3D. For example, one or more chips 410 can be a processor or a field programmable gate array (FPGA), and one or more of the chips 415 can be a HBM die stack and/or and one or more of the chips 415 can be a transceiver die.

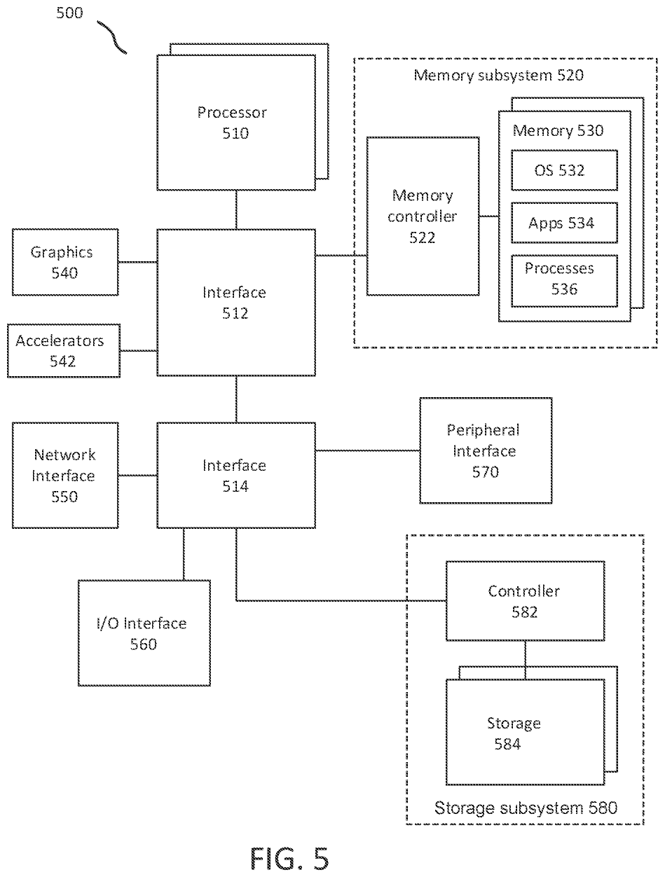

The semiconductor chips 110, 111, 410, and 415 can be, for example, any combination of microprocessors, CPUs (central processing units), GPUs (graphics processing units), processing cores, system on a chips, other processing hardware, a combination of processors or processing cores, programmable general-purpose or special-purpose microprocessors, accelerators, DSPs, I/O management, programmable controllers, ASICs, programmable logic devices (PLDs), HBM die stacks, and/or other memory devices. The semiconductor chips 110, 111, 410, and 415 can be any of the chips, for example, described herein with respect to FIG. 5. The interconnect bridge assemblies described herein generally can be used between semiconductor chips in various package configurations and the foregoing examples are not meant to limit the types of assemblies that are possible.

FIG. 5 depicts an example computing system. The computing system can be a system used for running equipment in a semiconductor fabrication plant. For example, instructions for operating semiconductor processing equipment or for performing one or more aspects of the process described in FIGS. 3A-3D can be stored and/or run on the computing system. The computing system employed can include more, different, or fewer features than the one described with respect to FIG. 5.

Computing system 500 includes processor 510, which provides processing, operation management, and execution of instructions for system 500. Processor 510 can include any type of microprocessor, CPU (central processing unit), GPU (graphics processing unit), processing core, or other processing hardware to provide processing for system 500, or a combination of processors or processing cores. Processor 510 controls the overall operation of system 500, and can be or include, one or more programmable general-purpose or special-purpose microprocessors, DSPs, programmable controllers, ASICs, programmable logic devices (PLDs), or the like, or a combination of such devices.

In one example, system 500 includes interface 512 coupled to processor 510, which can represent a higher speed interface or a high throughput interface for system components needing higher bandwidth connections, such as memory subsystem 520 or graphics interface components 540, and/or accelerators 542. Interface 512 represents an interface circuit, which can be a standalone component or integrated onto a processor die. Where present, graphics interface 540 interfaces to graphics components for providing a visual display to a user of system 500. In one example, the display can include a touchscreen display.

Accelerators 542 can be a fixed function or programmable offload engine that can be accessed or used by a processor 510. For example, an accelerator among accelerators 542 can provide data compression (DC) capability, cryptography services such as public key encryption (PKE), cipher, hash/authentication capabilities, decryption, or other capabilities or services. In some cases, accelerators 542 can be integrated into a CPU socket (e.g., a connector to a motherboard (or circuit board, printed circuit board, mainboard, system board, or logic board) that includes a CPU and provides an electrical interface with the CPU). For example, accelerators 542 can include a single or multi-core processor, graphics processing unit, logical execution unit single or multi-level cache, functional units usable to independently execute programs or threads, application specific integrated circuits (ASICs), neural network processors (NNPs), programmable control logic, and programmable processing elements such as field programmable gate arrays (FPGAs) or programmable logic devices (PLDs). Accelerators 542 can provide multiple neural networks, CPUs, processor cores, general purpose graphics processing units, or graphics processing units can be made available for use by artificial intelligence (AI) or machine learning (ML) models.

Memory subsystem 520 represents the main memory of system 500 and provides storage for code to be executed by processor 510, or data values to be used in executing a routine. Memory subsystem 520 can include one or more memory devices 530 such as read-only memory (ROM), flash memory, one or more varieties of random access memory (RAM) such as static RAM (SRAM), dynamic RAM (DRAM), synchronous DRAM (SDRAM) and/or or other memory devices, or a combination of such devices. Memory 530 stores and hosts, among other things, operating system (OS) 532 that provides a software platform for execution of instructions in system 500, and stores and hosts applications 534 and processes 536. In one example, memory subsystem 520 includes memory controller 522, which is a memory controller to generate and issue commands to memory 530. The memory controller 522 can be a physical part of processor 510 or a physical part of interface 512. For example, memory controller 522 can be an integrated memory controller, integrated onto a circuit within processor 510.

System 500 can also optionally include one or more buses or bus systems between devices, such memory buses, graphics buses, and/or interface buses. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a peripheral component interface (PCI) or PCI express (PCIe) bus, a Hyper Transport or industry standard architecture (ISA) bus, a small computer system interface (SCSI) bus, a universal serial bus (USB), or a Firewire bus.

In one example, system 500 includes interface 514, which can be coupled to interface 512. In one example, interface 514 represents an interface circuit, which can include standalone components and integrated circuitry. In one example, user interface components or peripheral components, or both, couple to interface 514. Network interface 550 provides system 500 the ability to communicate with remote devices (e.g., servers or other computing devices) over one or more networks. Network interface 550 can include an Ethernet adapter, wireless interconnection components, cellular network interconnection components, USB, or other wired or wireless standards-based or proprietary interfaces. Network interface 550 can transmit data to a device that is in the same data center or rack or a remote device, which can include sending data stored in memory.

Some examples of network interface 550 are part of an infrastructure processing unit (IPU) or data processing unit (DPU), or used by an IPU or DPU. An xPU can refer at least to an IPU, DPU, GPU, GPGPU (general purpose computing on graphics processing units), or other processing units (e.g., accelerator devices). An IPU or DPU can include a network interface with one or more programmable pipelines or fixed function processors to perform offload of operations that can have been performed by a CPU. The IPU or DPU can include one or more memory devices.

In one example, system 500 includes one or more input/output (I/O) interface(s) 560. I/O interface 560 can include one or more interface components through which a user interacts with system 500 (e.g., audio, alphanumeric, tactile/touch, or other interfacing). Peripheral interface 570 can include additional types of hardware interfaces, such as, for example, interfaces to semiconductor fabrication equipment and/or electrostatic charge management devices.

In one example, system 500 includes storage subsystem 580. Storage subsystem 580 includes storage device(s) 584, which can be or include any conventional medium for storing data in a nonvolatile manner, such as one or more magnetic, solid state, and/or optical based disks. Storage 584 can be generically considered to be a “memory,” although memory 530 is typically the executing or operating memory to provide instructions to processor 510. Whereas storage 584 is nonvolatile, memory 530 can include volatile memory (e.g., the value or state of the data is indeterminate if power is interrupted to system 500). In one example, storage subsystem 580 includes controller 582 to interface with storage 584. In one example controller 582 is a physical part of interface 512 or processor 510 or can include circuits or logic in both processor 510 and interface 514.

A power source (not depicted) provides power to the components of system 500. More specifically, power source typically interfaces to one or multiple power supplies in system 500 to provide power to the components of system 500.

Exemplary systems may be implemented in various types of computing, smart phones, tablets, personal computers, and networking equipment, such as switches, routers, racks, and blade servers such as those employed in a data center and/or server farm environment.

### Examples

A semiconductor package substrate can comprise: an interconnect bridge wherein the interconnect bridge includes metallic traces and metallic through-bridge vias, wherein the interconnect bridge has package-side landing pads, and wherein the package-side landing pads have a surface, and wherein the package-side landing pad surface has a dimension; and interconnect bridge-side landing pads wherein the interconnect bridge-side landing pads are electrically connected to the package-side landing pads, wherein the interconnect bridge-side landing pads have a surface, wherein the interconnect bridge-side landing pad surface has a dimension, and wherein the interconnect bridge-side landing pad surface dimension is 10% to 200% larger than the package-side landing pad surface dimension. The interconnect bridge-side landing pads can have a surface coating and the surface coating comprises Au. The interconnect bridge-side landing pads can have a surface coating and the surface coating comprises NiPdAu or NiAu. The interconnect bridge-side landing pad surface dimension can be 20% to 200% larger than the package-side landing pad surface dimension. The interconnect bridge-side landing pad surface dimension can be 50% to 200% larger than the package-side landing pad surface dimension. The package-side landing pad surface has a center, wherein the interconnect bridge-side landing pad surface has a center, and wherein the package-side landing pad surface center can be offset from the interconnect bridge-side landing pad surface center by an amount that is between 5 μm and 30 μm. The package substrate can be a coreless semiconductor package substrate. The semiconductor package substrate can also include a package substrate core that is comprised of glass or an organic material.

A semiconductor chip assembly can comprise: at least two semiconductor chips; a package substrate wherein the package substrate comprises: at least one interconnect bridge, wherein the interconnect bridge includes metallic traces and metallic through-bridge vias, wherein the interconnect bridge has package-side landing pads, wherein the package-side landing pads have a surface, wherein the package-side landing pad surface has a dimension; and interconnect bridge-side landing pads wherein the interconnect bridge-side landing pads are electrically connected to the package-side landing pads, wherein the interconnect bridge-side landing pads have a surface, wherein the interconnect bridge-side landing pad surface has a dimension, and wherein the interconnect bridge-side landing pad surface dimension is 10% to 200% larger than the package-side landing pad surface dimension, wherein a first semiconductor chip of the at least two semiconductor chips is communicatively coupled to a second semiconductor chip of the at least two semiconductor chips through the interconnect bridge. The interconnect bridge-side landing pads can have a surface coating and wherein the surface coating comprises Au. The interconnect bridge-side landing pad surface dimension can be 20% to 200% larger than the package-side landing pad surface dimension. The package-side landing pad surface has a center, the interconnect bridge-side landing pad surface has a center, and the package-side landing pad surface center can be offset from the interconnect bridge-side landing pad surface center by an amount that is between 5 μm and 30 μm. A first semiconductor chip of the at least two semiconductor chips can be a processor and a second semiconductor chip of the at least two semiconductor chips can be a high bandwidth memory dynamic random access memory chip. The semiconductor chip assembly can also include a circuit board, wherein the package substrate is operably coupled to the circuit board, wherein the circuit board comprises a power supply, and wherein the power supply is capable of providing power to the at least two semiconductor chips through the interconnect bridge.

A method of manufacturing a semiconductor package substrate can comprise: creating a cavity in a partially manufactured semiconductor package substrate to expose interconnect bridge-side landing pads within the partially manufactured semiconductor package substrate; coating the exposed interconnect bridge-side landing pads with a metallic material; placing an interconnect bridge into the cavity wherein electrical interconnections are formed between the interconnect bridge and the interconnect bridge-side landing pads within the partially manufactured semiconductor package substrate and wherein interconnect bridge is aligned with fiducials that are in the partially manufactured semiconductor package substrate; and placing an underfill between the interconnect bridge and the partially manufactured semiconductor package substrate. The interconnect bridge can include package-side landing pads, the interconnect bridge-side landing pads can be electrically connected to the package-side landing pads, wherein the interconnect bridge-side landing pads have a surface, wherein the interconnect bridge-side landing pad surface has a dimension, wherein the package-side landing pads have a surface, wherein the package-side landing pad surface has a dimension, and wherein the interconnect bridge-side landing pad surface dimension can be 10% to 200% larger than the package-side landing pad surface dimension. The coating can comprise Au. The coating can partially cover a surface of the exposed interconnect bridge-side landing pads. The coating can cover the exposed portions of the interconnect bridge-side landing pads. The coating can fully cover a surface of the exposed interconnect bridge-side landing pads.

Besides what is described herein, various modifications can be made to what is disclosed and implementations of the invention without departing from their scope. Therefore, the illustrations and examples herein should be construed in an illustrative, and not a restrictive sense. The scope of the invention should be measured solely by reference to the claims that follow.

What is claimed is:

1. A semiconductor package substrate comprising:
an interconnect bridge wherein the interconnect bridge includes metallic traces and metallic through-bridge vias, wherein the interconnect bridge has package-side landing pads, and wherein the package-side landing pads have a surface, and wherein the package-side landing pad surface has a dimension; and
interconnect bridge-side landing pads wherein the interconnect bridge-side landing pads are electrically connected to the package-side landing pads, wherein the interconnect bridge-side landing pads have a surface, wherein the interconnect bridge-side landing pad surface has a dimension, and wherein the interconnect bridge-side landing pad surface dimension is 10% to 200% larger than the package-side landing pad surface dimension.

2. The semiconductor package substrate of claim 1 wherein the interconnect bridge-side landing pads have a surface coating and wherein the surface coating comprises Au.

3. The semiconductor package substrate of claim 1 wherein the interconnect bridge-side landing pads have a surface coating and wherein the surface coating comprises NiPdAu or NiAu.

4. The semiconductor package substrate of claim 1 wherein the interconnect bridge-side landing pad surface dimension is 20% to 200% larger than the package-side landing pad surface dimension.

5. The semiconductor package substrate of claim 1 wherein the interconnect bridge-side landing pad surface dimension is 50% to 200% larger than the package-side landing pad surface dimension.

6. The semiconductor package substrate of claim 1 wherein the package-side landing pad surface has a center, wherein the interconnect bridge-side landing pad surface has a center, and wherein the package-side landing pad surface center is offset from the interconnect bridge-side landing pad surface center by an amount that is between 5 μm and 30 μm.

7. The semiconductor package substrate of claim 1 wherein the package substrate is a coreless semiconductor package substrate.

8. The semiconductor package substrate of claim 1 also including a package substrate core that is comprised of glass or an organic material.

9. A semiconductor chip assembly comprising:
at least two semiconductor chips;
a package substrate wherein the package substrate comprises:
at least one interconnect bridge, wherein the interconnect bridge includes metallic traces and metallic through-bridge vias, wherein the interconnect bridge has package-side landing pads, wherein the package-side landing pads have a surface, wherein the package-side landing pad surface has a dimension; and
interconnect bridge-side landing pads wherein the interconnect bridge-side landing pads are electrically connected to the package-side landing pads, wherein the interconnect bridge-side landing pads have a surface, wherein the interconnect bridge-side landing pad surface has a dimension, and wherein the interconnect bridge-side landing pad surface dimension is 10% to 200% larger than the package-side landing pad surface dimension,
wherein a first semiconductor chip of the at least two semiconductor chips is communicatively coupled to a second semiconductor chip of the at least two semiconductor chips through the interconnect bridge.

10. The semiconductor chip assembly of claim 9 wherein the interconnect bridge-side landing pads have a surface coating and wherein the surface coating comprises Au.

11. The semiconductor chip assembly of claim 9 wherein the interconnect bridge-side landing pad surface dimension is 20% to 200% larger than the package-side landing pad surface dimension.

12. The semiconductor chip assembly of claim 9 wherein the package-side landing pad surface has a center, wherein the interconnect bridge-side landing pad surface has a center, and wherein the package-side landing pad surface center is offset from the interconnect bridge-side landing pad surface center by an amount that is between 5 μm and 30 μm.

13. The semiconductor chip assembly of claim 9 wherein a first semiconductor chip of the at least two semiconductor chips is a processor and wherein a second semiconductor chip of the at least two semiconductor chips is a high bandwidth memory dynamic random access memory chip.

14. The semiconductor chip assembly of claim 9 also including a circuit board, wherein the package substrate is operably coupled to the circuit board, wherein the circuit board comprises a power supply, and wherein the power supply is capable of providing power to the at least two semiconductor chips through the interconnect bridge.

15. A method of manufacturing a semiconductor package substrate comprising:
creating a cavity in a partially manufactured semiconductor package substrate to expose interconnect bridge-side landing pads within the partially manufactured semiconductor package substrate;
coating the exposed interconnect bridge-side landing pads with a metallic material;
placing an interconnect bridge into the cavity wherein electrical interconnections are formed between the interconnect bridge and the interconnect bridge-side landing pads within the partially manufactured semiconductor package substrate and wherein interconnect bridge is aligned with fiducials that are in the partially manufactured semiconductor package substrate; and
placing an underfill between the interconnect bridge and the partially manufactured semiconductor package substrate.

16. The method of manufacturing a semiconductor package substrate of claim 15 wherein the interconnect bridge includes package-side landing pads, wherein the interconnect bridge-side landing pads are electrically connected to the package-side landing pads, wherein the interconnect bridge-side landing pads have a surface, wherein the interconnect bridge-side landing pad surface has a dimension, wherein the package-side landing pads have a surface, wherein the package-side landing pad surface has a dimension, and wherein the interconnect bridge-side landing pad surface dimension is 10% to 200% larger than the package-side landing pad surface dimension.

17. The method of manufacturing a semiconductor package substrate of claim 15 wherein the coating comprises Au.

18. The method of manufacturing a semiconductor package substrate of claim 15 wherein the coating partially covers a surface of the exposed interconnect bridge-side landing pads.

19. The method of manufacturing a semiconductor package substrate of claim 15 wherein the coating covers the exposed portions of the interconnect bridge-side landing pads.

20. The method of manufacturing a semiconductor package substrate of claim 15 wherein the coating fully covers a surface of the exposed interconnect bridge-side landing pads.
